(19) United States
(12) Patent Application Publication
(10) Pub. No.: US 2011/0247859 A1
(43) Pub. Date: Oct. 13, 2011

(54) METHOD FOR MANUFACTURING A SUBMILLIMETRIC ELECTRICALLY CONDUCTIVE GRID, AND SUBMILLIMETRIC ELECTRICALLY CONDUCTIVE GRID

(76) Inventors: Georges Zagdoun, La Garenne Colombes (FR); Bernard Nghiem, Arsy (FR); Emmanuel Valentin, Le Plessis Trevise (FR); Eddy Royer, Villemomble (FR)

(21) Appl. No.: 13/120,567

(22) PCT Filed: Sep. 25, 2009
(86) PCT No.: PCT/FR2009/051821

§ 371 Date: Jun. 24, 2011

(30) Foreign Application Priority Data
Sep. 25, 2008 (FR) 0856446

(51) Int. Cl. H05K 1/00; C23C 16/01; C25D 1/20; B22C 7/00; C25D 5/02; C04B 35/00; B44C 1/17

(52) U.S. Cl. 174/250; 264/104; 264/81; 156/231; 164/45; 205/125; 205/78

(57) ABSTRACT

The manufacture of a submillimetric grid includes the production of a mask having submillimetric openings, referred to as a network mask, on the main face, from a solution of colloidal nanoparticles with a given glass transition temperature T_{g}, the drying of the masking layer at a temperature below the T_{g}; the formation of the electroconductive grid from the network mask including in this order: deposition of at least one electroconductive material, referred to as grid material, having an electricity resistivity of less than 10⁻⁵ ohm.cm; removal of the masking layer, revealing the mother grid; optional deposition, by electrodeposition, of an electroconductive material, referred to as overgrid material, the surface subjacent to the mother grid then being dielectric; a detachment, of the mother grid or the overgrid, of a thickness of at least 500 nm. The invention also relates to the detached grid.

The present invention relates to a process for producing a submillimetric electroconductive grid and to such a grid.

Manufacturing techniques are known that make it possible to obtain micron-size metal grids. These have the advantage of attaining surface resistances of less than 1 ohm/square while retaining a light transmission (T_{L}) of around 75 to 85%. The process for producing these grids is based on a technique of etching a metal layer either by a photolithographic process combined with a process for chemical attack via a liquid route, or by a laser ablation technique. For example, use is made of a 10 μm copper foil bonded by an epoxy-type adhesive to a plastic film made of polyethylene terephthalate (PET). The foil is coated with a resist and exposed to light through a mask in order to thus form the grid. This manufacture results in an unacceptable manufacturing cost and requires a large number of steps. The price furthermore increases exponentially with the size of the grid.

Moreover, self-supported electroconductive grids based on the weaving of metal or metal-covered polymer wires are known, which are used for electromagnetic shielding. These grids have strands that have a dimension of at least 20 μm. These grids are not very strong mechanically, with flatness defects, and require a controlled tension during the weaving and the implementation, or else there is a risk of numerous defects, deformation of the meshes, tearing, unraveling, etc.

The present invention therefore aims to overcome the drawbacks of the prior art processes by proposing a process for manufacturing an electroconductive submillimetric grid that is economical, reproducible and that can be used on any type of support.

The optical properties and/or the electrical conductive properties of this grid are at least comparable to those of the prior art.

For this purpose, a first subject of the invention is a process for manufacturing a submillimetric grid, in particular a submicron-sized (at least for the grid width) grid, on a main face of a substrate, in particular a flat substrate, comprising:
producing a mask having submillimetric openings, referred to as a network mask, (directly or indirectly) on the main face, including:
   the deposition of a masking layer from a solution of colloidal nanoparticles that are stabilized and dispersed in a solvent, the nanoparticles having a given glass transition temperature T_{g};
   the drying of the masking layer at a temperature below said temperature T_{g} until the mask having a network of openings with substantially straight edges of mask zones (over the entire thickness) is obtained;
the formation of the electroconductive grid from the network mask, comprising in this order:
   a deposition of at least one electroconductive material, referred to as grid material, having an electrical resistivity of less than 10⁻⁵ ohm.cm, more preferably still having an electrical resistivity of less than 10⁻⁶ ohm.cm, preferably a metallic material, until a fraction of the depth of the openings is filled;
   a removal of the masking layer, until an electroconductive grid, referred to as the mother grid, is revealed;
   an optional deposition, by electrodeposition (selective deposition), of an electroconductive material, referred to as overgrid material, directly on the optionally surface-treated grid material, thus forming an overgrid, the surface subjacent to the mother grid then being dielectric (electrically insulating);
the process comprising, in addition, a detachment (without significant strand rupture), of at least said mother grid or of at least the overgrid, over a thickness of at least 500 nm.

Firstly, the mask having a network of openings according to the invention and its method of manufacture according to the invention have a certain number of advantages.

The mask thus has a random aperiodic structure along at least one characteristic direction of the network (therefore parallel to the surface of the substrate), or even along two (all) directions. The arrangement of the strands of the mother grid (and of the optional overgrid) may then be substantially the replica of that of the of network of openings.

The thickness of the mask may be submicron-sized up to several tens of microns. The thicker the mask layer is, the larger A (respectively B) is.

The edges of the network mask zones are substantially straight, that is to say along a midplane between 80 and 100° relative to the surface (if the surface is curved, relative to the tangential plane), or even between 85° and 95°.

Due to the straight edges, the deposited layer is discontinuous (no or little deposition along the edges) and it is thus possible to remove the coated mask without damaging the mother grid. For reasons of simplicity, directional techniques for deposition of the grid material may be favored. The deposition may be carried out both through the openings and over the mask.

It is possible to clean the network of openings using an atmospheric pressure plasma source.

In order to obtain the substantially straight edges, it is necessary to both:
choose particles of limited size, therefore nanoparticles, in order to promote their dispersion, preferably with at least one characteristic (mean) dimension, for example the mean diameter, of between 10 and 300 nm, or even between 50 and 150 nm; and
stabilize the nanoparticles in the solvent (especially by treatment via surface charges, for example via a surfactant, by control of the pH), to prevent them from agglomerating together, from precipitating and/or from falling due to gravity.

In addition, the concentration of the nanoparticles is adjusted, preferably between 5%, or even 10% and 60% by weight, more preferably still between 20% and 40%. The addition of a binder is avoided (or in a small enough amount so as not to influence the mask).

Owing to this particular process, it is possible to obtain, at a lower cost, a mask composed of random (shape and/or size), aperiodic patterns of suitable characteristic dimensions:
(mean) width of the openings of the network A is micron-sized, or even nanoscale, in particular between a few hundreds of nanometers to a few tens of microns, especially between 200 nm and 50 μm;
(mean) size of pattern B (therefore size between adjacent openings) is millimetric or even submillimetric, especially between 5 and 500 μm, or even from 100 to 250 μm;
B/A ratio is adjustable, in particular, as a function of the nature of the particles, especially between 7 and 20 or even 40;
difference between the maximum width of the openings and the minimum width of the openings is less than 4, or even less than or equal to 2, in a given region of the mask, or even over the majority or the whole of the surface;
difference between the maximum pattern dimension and the minimum pattern dimension is less than 4, or even less than or equal to 2, in a given region of the mask, or even over the majority or even over the whole of the surface;
the amount of open pattern (non-through or “blind” opening), in other words the amount of interconnection rupture, is less than 5%, or even less than or equal to 2%, in a given region of the mask, or even over the majority or the whole of the surface, therefore with limited or even almost zero network rupture, which is optionally reduced and can be eliminated by etching of the network;
for a given pattern, the majority or even all of the patterns, in a given region or over the whole of the surface, the difference between the largest characteristic dimension of the pattern and the smallest characteristic dimension of the pattern is less than 2, in order to strengthen the isotropy; and
for the majority or even all of the segments of the network, the edges are constantly spaced, parallel, in particular on a scale of 10 μm (for example, observed with an optical microscope with a magnification of 200).

The width A may be, for example, between 1 and 20 μm, or even between 1 and 10 μm, and B may be between 50 and 200 μm.

Via the process of the invention it is thus possible to form a mesh of openings, which may be spread over the whole surface, making it possible to obtain isotropic properties.

The patterns delimited by the openings (and therefore the meshes of the mother grids and/or overgrids obtained) are of diverse shapes, typically with three, four or five sides, for example predominantly with four sides, and/or of diverse sizes, distributed randomly and aperiodically.

For the majority or all of the patterns (respectively the meshes), the angle between two adjacent sides of a mesh may be between 60° and 110°, especially between 80° and 100°.

In one configuration, a main network is obtained with openings (optionally approximately parallel) and a secondary network of openings (optionally approximately perpendicular to the parallel network), the location and the distance of which are random. The secondary openings have a width, for example, smaller than the main openings.

This makes it possible to subsequently produce a mother grid (and/or an overgrid) that is defined by a mean strand width A′ that is substantially identical to the width of the openings A and a (mean) space between the strands B′ that is substantially identical to the space between the openings B (of a mesh).

In particular, the sizes of the strands A′ may preferably be between a few tens of microns and a few hundreds of nanometers. The ratio B′/A′ may be chosen between 7 and 20, or even 30 to 40.

Moreover, the characteristic dimensions of the grids of the prior art made by photolithography, generally of regular and periodic shape (square, rectangular), form networks of 20 to 30 μm wide metal strands spaced, for example, 300 μm apart, which are the source, when they are illuminated by a point light source, of diffraction patterns. And it would be even more difficult and expensive to make grids with random patterns. Each pattern to be produced would require a specific mask.

This manufacturing technique of the prior art furthermore has a resolution limit of around a few tens of μm, leaving the patterns esthetically visible.

The weaving of very fine wires itself also has flaws, especially the need for a relatively large diameter of the wires (>40 μm). And the weaving can only produce periodic patterns.

The network mask according to the invention therefore makes it possible to envision, at lower cost, irregular grids (mother grid and/or overgrid) of other shapes, of any size. Thus the grid is random in at least one (grid) direction.

According to the invention, the dimensions of the strands may be very small (a few μm) and the thicknesses of the strands relatively small (with a minimum thickness of 500 nm for a good cohesion of the detached grid). Therefore, the grids may have a low electrical resistance (<2 ohm) and a high light transmission (>80%).

The process uses a mask manufactured from the drying of a colloidal solution, thus the deposition surface of the mask is necessarily chemically stable with water or other solvents used and in the event of a hydrophilic aqueous solvent.

The adhesion of the grid to be detached (mother grid alone, overgrid alone, mother grid and overgrid together) is controlled, with its subjacent surface, so that, on the one hand, this grid can withstand all of the steps necessary for its manufacture and so that, on the other hand, the adhesion is low enough at the end of the process so that the grid can easily be detached from its substrate.

The fact that this grid is detachable makes it possible to transfer it to any substrate, for example a support that does not withstand one or more of the (chemical, thermal, etc.) steps for manufacturing the network mask and/or the (mother) grid.

The detachable grid may, for example, be self-supported.

The detachable grid is sufficiently weakly adhering in order to be detached from the subjacent surface.

Let σₜ be the tensile stress exerted on a strand of the grid to be detached in order to separate it from the subjacent surface.

Let σᵣₑₛ be the residual stress in general compressive stress in this strand of the grid resulting from the deposition technique.

Let t be the thickness of the grid which is considered to be small relative to the width of the strand.

Let ν be the modulus.

Let σₚₗₐₛₜ be the yield strength of the electroconductive material of the grid to be detached.

Let G_{adh} be the adhesion energy of the grid to be detached on the subjacent surface.

The conditions for the peeling of the grid are written:

$${σ}_{t} << {σ}_{plast}$$

$$\frac{( 1 - v )}{E} t ( {σ}_{t}^{2} + {σ}_{res}^{2} ) >> {G}_{adh}$$

In other words, it is arranged so that the adhesion is typically low enough for the tensile stress in the grid to be below the yield strength and so that the mechanical energy stored during the detachment is greater than that of the adhesion.

That is to say, a quite simple condition relating to the adhesion energy for a given electroconductive material:

$$\frac{( 1 - v )}{E} t ( {σ}_{plast}^{2} + {σ}_{res}^{2} ) >> {G}_{adh}$$

Within the meaning of the present invention, there is no significant rupture of strands if the amount of rupture of interconnections between strands after detachment is low, less than or equal to 10%, more preferably still less than or equal to 1%.

The amount of strands broken is defined in the manner described below:

Take an SEM photo of the grid of size nL×mL (L being the mean size of the mesh). Let K be the number of strands broken in this photo (it is necessary that n and m are large compared to 1, typically >10).

The amount of strands broken T is written, by definition:

$$T = \frac{K}{2 mn + m + n} \times 100$$

Another satisfactory method for (electrically) validating a detached grid is to measure its sheet resistance before and after detachment. It is then preferred that the difference between the sheet resistance after detachment and before detachment is less than or equal to 10%. Non-destructive detachment is rendered possible by choosing a sufficient thickness of material to guarantee the cohesion of the detached grid.

Starting from a thickness of the part to be detached of 1 μm, or even 2 μm, the detachment is even easier.

In a first embodiment, the mother grid and the optional overgrid are detached.

For example, as the electroconductor material, a metallic material is chosen, for example silver and gold, deposited by physical vapor deposition, especially by magnetron sputtering or by evaporation.

It is possible, for example, to deposit at least 500 nm of silver.

For example, for a low adhesion the following are chosen as the subjacent surface:
the substrate, especially a glass;
a permanent (non-detachable) sublayer that favors the detachment (“mold release” layer), such as a layer of fluoropolymer, in particular of polytetrafluoroethylene PTFE, a layer of carbon, especially graphite, or a layer of boron nitride.

This permanent sublayer may be continuous (deposited before formation of the mask), or discontinuous, for example deposited after formation of the mask through the openings. A mold release sublayer deposited after formation of the mask is preferred when its surface is hydrophobic and when the solvent of the mask is aqueous.

For the detachment of the mother grid and of the overgrid (or of the overgrid alone), a metallic layer is deposited by electrolysis as the overgrid material. The deposition is thus completed by an electrolytic recharge using an electrode made of Ag, Cu, Au or another usable metal with high conductivity.

The substrate is not necessarily flat, for example it may be curved (bent, on a roll or forming a roll). For the deposition by electrolysis, it is arranged for the two electrodes to be a constant distance apart.

The thickness of the overgrid may preferably be greater than or equal to 1 μm, or even greater than or equal to 2 μm.

In order to increase the thickness of the metallic grid layer and thus to reduce the electrical resistance of the grid, an overlayer is therefore deposited by electrolysis (soluble anode method) on the mother grid. This process actually makes it possible to attain an extremely low sheet resistance (<0.5 ohm) while retaining a good transmission. The use of this supplementary step makes it possible to obtain an excellent material yield, which is economically advantageous when precious metals are used for example for the mother grid. This technique is, in addition, the only one that makes it possible to deposit a metallic layer locally and with a high deposition rate without having to resort to a subsequent masking or etching step.

In the case of the detachment of at least the mother grid, in order to facilitate the transfer and/or the handling of the detached part, the formation of a peripheral (and/or central) mechanical reinforcement zone for the grid by deposition of electroconductive grid material(s) on a surface adjacent to and in contact with the network mask may be preferred. Preferably, this zone surrounds the grid (and its optional overgrid).

In order to form the mechanical reinforcement zone, a partial removal of the mask may first be carried out before the electroconductive deposition of the mother grid. The peripheral mechanical reinforcement zone may be made of the mother grid deposition material: the material is deposited simultaneously through the network mask and over the adjacent zone without mask.

Due to the nature of the masking layer, it is possible, in addition, to selectively remove a portion of the network mask without damaging it or damaging the subjacent surface by the mild and simple means which are optical and/or mechanical means.

The material of the network mask has a mechanical strength that is low enough for it to be removed without damaging the subjacent surface, but that remains high enough to withstand the steps of the process for depositing the electroconductive grid material.

Such a removal of the network mask, preferably which is automated, may be carried out:
by mechanical action, in particular by blowing (focused airflow, etc.), by rubbing with a non-abrasive element (of the felt, fabric, eraser type) or by cutting with a cutting element (a blade, etc.);
and/or by sublimation or by a laser-type means.

It is possible to choose the type of removal as a function of the desired resolution, and of the effect on the edges of the mask remaining in contact with the removal means.

In one embodiment, it is possible to carry out a liquid deposition of the masking solution over the entire face of the substrate, which is simpler to do, and to partially remove the network mask in particular:
at least along one edge of the network mask (preferably close to the edge of the substrate) in order to create at least one solid strip (for the reinforcement or even the connection system and/or for other electrical functions);
along two edges of the network mask in order to form two opposite solid strips or over two adjacent edges; and
to provide a (complete) outline of the network mask in particular to create a solid strip around the entire perimeter of the mother grid (rectangular frame, ring, etc.).

Conversely, a mother grid may be chosen that is very chemically robust and highly adherent to the subjacent surface which acts as an anode and also as a “mother matrix” for the production of an overgrid by electrodeposition.

For a detachment of the overgrid alone, the mother grid, made of a metallic material chosen from gold, silver and/or copper, is deposited optionally by physical vapor deposition (evaporation or magnetron sputtering) over a sublayer (a single layer or multilayer) that promotes adhesion of the grid material, in particular NiCr, Ti, Al, Nb or a single or mixed, doped or undoped metal oxide (ITO, etc.).

Or else the mother grid, made of a metallic material chosen from gold, silver and/or copper, is deposited optionally by physical vapor deposition (evaporation or magnetron sputtering) onto a suitable plastic (which is hydrophilic if necessary and to which the grid adheres well) such as a PET (for example plasma-treated in order to be hydrophilic, if necessary), a PMMA (for example plasma-treated in order to be hydrophilic if necessary) or a polycarbonate (PC).

For a detachment of the overgrid alone, the mother grid may also be made of a metallic material chosen from Ti, Mo, W, Co, Nb or Ta (materials compatible with electrodeposition) that adheres sufficiently to the chosen substrate such as a glass or a suitable plastic to which the grid adheres well (and which is hydrophilic if necessary) such as PET (for example plasma-treated in order to be hydrophilic if necessary), a PMMA (for example plasma-treated in order to be hydrophilic if necessary) or a polycarbonate (PC).

For a detachment of the overgrid alone, the metallic mother grid may be surface-treated with a layer referred to as a “mold release layer”, preferably having a thickness of less than or equal to 10 nm, optionally which is non-coalescing, in particular:
an organosilane layer (a few thicknesses of molecules, less than 2 nm), in particular an organofluorosilicon layer;
a layer of carbon, in particular graphite, of a few nm;
a layer of fluoropolymer, a layer of teflon (PTFE);
a layer of (hexagonal) boron nitride;
a layer of stearic acid.

Furthermore, the formation of the overgrid and the detachment of the overgrid alone may be carried out continuously, in particular:
the mother grid is on a part rotating about a fixed axis (longitudinal axis), typically a roll, the grid being directly on the surface of the part or on a first film, in particular a flexible film, added to the part;
the mother grid is partially immersed in an electrolysis bath for the electrodeposition; and
on exiting the bath, the overgrid on the mother grid comes into contact with a second film, in particular a flexible film, on a rotating counterpart for transfer of the overgrid alone.

And preferably, the second film, in particular flexible film, is a temporary transfer substrate, which is perforated or porous for washing of the overgrid, the overgrid being transferred by contact without being bonded to said temporary film. After the washing and a continuous drying, the overgrid is transferred to another film, preferably a flexible film, which is preferably a lamination interlayer (PVB, EVA, silicone, etc.).

The detachment of the mother grid and/or of the overgrid may be carried out manually (simple gripping) or by a robot. The mother grid and/or the overgrid may be self-supported, manipulated before being transferred.

The detachment of at least said mother grid or of at least the overgrid, referred to as the detachable part, may be carried out by applying an adhesive polymer film having a tack of less than the surface subjacent to the part to be detached and having a tack greater than that of the part to be detached, the application being via a conventional method such as calendering for example, then by removal of the polymer film bearing the detached part.

In particular, an interlayer polymer film (with a view to lamination) is preferred, for example:
polyvinylbutyral PVB;
ethylene/vinyl acetate EVA;
polyurethane PU;
or silicone.

The substrate receiving the mask or the transfer substrate may be flat, curved (bent, etc.), or may be a roll.

Its main faces may be rectangular, square or even of any other shape (round, oval, polygonal, etc.). This substrate may be of a large size, for example having a surface area greater than 0.02 m², or even 0.5 m² or 1 m².

The substrate receiving the mask may also be opaque, semi-transparent, for example a glass-ceramic, a metal plate, a plastic, etc.

The transfer substrate may be substantially transparent, inorganic or made of a plastic such as polycarbonate (PC) or polymethyl methacrylate (PMMA), or else PET, polyvinyl butyral (PVB), polyurethane (PU), polytetrafluoroethylene (PTFE), etc.

The substrate receiving the mask may comprise a sublayer (especially a base layer, closest to the substrate), which is continuous (underneath the masking layer) and capable of being a barrier to alkali metals.

The transfer substrate may comprise a sublayer (especially a base layer, closest to the substrate), which is continuous (capable of being a barrier to alkali metals).

Such a base layer protects the mother grid material from any pollution (pollution which may lead to mechanical defects such as delaminations), in the case of an electroconductive deposition (to form the electrode in particular), and additionally preserves its electrical conductivity.

The base layer is robust, quick and easy to deposit according to various techniques. It can be deposited, for example, by a pyrolysis technique, especially as a chemical vapor phase (technique often denoted by the abbreviation CVD for “chemical vapor deposition”). This technique is advantageous for the invention since suitable adjustments of the deposition parameters make it possible to obtain a very dense layer for a reinforced barrier.

The base layer may optionally be doped with aluminum and/or boron to render its deposition under vacuum more stable. The base layer (a single layer or multilayer, optionally doped) may have a thickness between 10 and 150 nm, more preferably still between 15 and 50 nm.

The base layer may preferably be:
based on silicon oxide, silicon oxycarbide, a layer of general formula SiOC;
based on silicon nitride, silicon oxynitride, silicon oxycarbonitride, a layer of general formula SiNOC, especially SiN, in particular Si₃N₄.

Very particularly, a base layer (predominantly) made of doped or undoped silicon nitride Si₃N₄ may be preferred. Silicon nitride is deposited very rapidly and forms an excellent barrier to alkali metals.

The surface for the deposition of the masking layer is a film-forming surface, in particular preferably a hydrophilic surface if the solvent is aqueous. This is the surface:
of the substrate: glass, plastic (PU, PC) that is optionally treated (by plasma for example) such as PET, PMMA;
or of an optionally functional added sublayer:
   hydrophilic layer (silica layer, for example on hydrophobic plastic, such as PET and PMMA) and/or an alkali-metal barrier layer;
   and/or (as last layer) a layer for promoting the adhesion of the grid material, if it is desired to keep the mother grid, as already seen;
   and/or a (transparent) electroconductive layer, and/or a decorative, colored or opaque layer.

Between the mask layer and the substrate there may be several sublayers.

In preferred embodiments of the invention, it is possible to optionally resort, in addition, to one and/or the other of the following arrangements:
the deposition of the grid material fills both a fraction of the mask openings and also covers the surface of the mask; and
the deposition of the grid material is an atmospheric pressure deposition, especially by plasma, a deposition under vacuum, by sputtering, by evaporation.

It is thus possible to then choose one or more deposition techniques that can be carried out at ambient temperature and/or that are simple (especially simpler than a catalytic deposition that inevitably requires a′ catalyst) and/or that give dense deposits.

The methods for depositing the metallic layer may be of vacuum thermal evaporation type, which is optionally plasma-assisted (technique developed by Fraunhofer of Dresden): they have deposition rates greater than those obtained by magnetron sputtering.

By varying the B′/A′ ratio (space between the strands B′ over the width of the strands A′ size of the strands), haze values between 1 and 20% are obtained for the grid.

Drying causes a contraction of the masking layer and friction of the nanoparticles at the surface resulting in a tensile stress in the layer which, via relaxation, forms the openings.

Drying results, in one step, in the elimination of the solvent and in the formation of the openings.

After drying, a stack of nanoparticles is thus obtained, in the form of clusters of variable size that are separated by the openings that are themselves of variable size. The nanoparticles remain discernible even if they may aggregate together. The nanoparticles are not melted to form a continuous layer.

The drying is carried out at a temperature below the glass transition temperature for the creation of the network of openings. Indeed, it has been observed that above this glass transition temperature a continuous layer, or at the very least a layer without openings running through the entire thickness, was formed.

Thus, a weakly adherent layer simply composed of a stack of (hard), preferably spherical, nanoparticles is deposited on the substrate. These hard nanoparticles do not establish strong chemical bonds, either between themselves or with the surface of the substrate. The cohesion of the layer is provided all the same by weak forces, of the van der Waals forces or electrostatic forces type.

The mask obtained is capable of easily being eliminated using cold or warm pure water, in particular with an aqueous solvent, without requiring highly basic solutions or potentially polluting organic compounds.

By choosing a high enough Tg for the nanoparticles of the solution, the drying step (like preferably the deposition step) may be carried out (substantially) at a temperature below 50° C., preferably at ambient temperature, typically between 20° and 25° C. Thus, unlike the sol-gel mask, annealing is not necessary.

The difference between the given glass transition temperature T_{g} of the particles of the solution and the drying temperature preferably being greater than 10° C., or even 20° C.

The step of drying the masking layer may be carried out substantially at atmospheric pressure rather than drying under vacuum for example.

It is possible to modify the drying parameters (control parameters), especially the degree of moisture and the drying rate, in order to adjust the distance between the openings B, the size of the openings A, and/or the B/A ratio.

The higher the moisture is (all things otherwise being equal), the lower A is.

The higher the temperature is (all things otherwise being equal), the higher B is.

It is possible to deposit a solution (aqueous or non-aqueous) of colloids via standard liquid techniques.

It is possible to modify other control parameters chosen from the friction coefficient between the compacted colloids, in particular by nanotexturing of the substrate and the surface of the substrate, the size of the nanoparticles and the initial particle concentration, the nature of the solvent and the thickness that is dependent on the deposition technique, in order to adjust B, A and/or the B/A ratio.

The higher the concentration is (all things otherwise being equal), the lower B/A is.

As wet techniques, mention is made of:
spin coating;
curtain coating;
dip coating;
spray coating; and
flow coating.

The solution may be naturally stable, with nanoparticles that are already formed, and preferably contains no (or a negligible amount of) reactive element of polymer precursor type.

The solvent is preferably water-based, or even entirely aqueous.

In a first embodiment, the solution of colloids comprises polymeric nanoparticles (preferably with a solvent that is water-based, or even entirely aqueous).

For example, acrylic copolymers, styrenes, polystyrenes, poly(meth)acrylates, polyesters or mixtures thereof are chosen.

The masking layer (before drying) may thus be essentially composed of a stack of colloidal nano-particles (therefore nanoparticles of a material that is insoluble in the solvent) that are discernible and in particular are polymeric.

The polymeric nanoparticles may preferably be composed of a solid, water-insoluble polymer.

The expression “essentially composed” is understood to mean that the masking layer may optionally comprise other compounds, as traces, and which do not have an influence on the properties of the mask (formation of the network, easy removal, etc.).

The colloidal aqueous solution is preferably composed of water and of polymeric colloidal particles, to the exclusion therefore of any other chemical agent (such as, for example, pigments, binders, plasticizers, etc.). Likewise, the colloidal aqueous dispersion is preferably the only compound used to form the mask.

The network mask, after drying, may thus be essentially composed of a stack of nanoparticles, preferably polymeric, discernible nanoparticles. The polymeric nanoparticles are composed of a solid, water-insoluble polymer.

The solution may comprise, alternatively or cumulatively, inorganic nanoparticles, preferably of silica, alumina or iron oxide.

Preferably, the removal of the mask is carried our via a liquid route, by a solvent that is inert for the grid, for example water, acetone or alcohol, (optionally at high temperature and/or assisted by ultrasound).

It is possible to clean the network of openings prior to the deposition of the grid material being carried out.

The invention also relates to a detached grid, in particular that is self-supported, formed from the manufacturing process already defined previously.

The grid (mother grid alone, mother grid and overgrid, overgrid alone) may be irregular, that is to say a two-dimensional meshed network of strands with random, aperiodic meshes (closed patterns delimited by the strands).

The grid (mother grid alone, mother grid and overgrid, overgrid alone) may have one or more of the following characteristics:
a ratio of the (mean) space between the strands (B′) to the submillimetric (mean) width of the strands (A′) of between 7 and 40;
the grid patterns are random (aperiodic) and of diverse shape and/or size;
the meshes have three and/or four and/or five sides, for example mostly four sides;
the grid has an aperiodic (or random) structure in at least one direction, preferably in two directions;
for most, or even all, of the meshes in a given region or over the entire surface, the difference between the largest characteristic dimension of the mesh and the smallest characteristic dimension of the mesh is less than 2;
for most, or even all, of the meshes, the angle between two adjacent sides of one mesh may be between 60° and 110°, especially between 80° and 100°;
the difference between the maximum width of the strands and the minimum width of the strands is less than 4, or even less than or equal to 2, in a given grid region, or even over the majority or all of the surface;
the difference between the maximum mesh dimension (space between strands forming a mesh) and the minimum mesh dimension is less than 4, or even less than or equal to 2, in a given grid region, or even over the majority or all of the surface;
for the most part, the strand edges are constantly spaced, in particular substantially linear, parallel, on a scale of 10 μm (for example observed with an optical microscope with a magnification of 200).

The grid (mother grid alone, mother grid and overgrid, overgrid alone) according to the invention may have isotropic electrical properties.

The irregular grid according to the invention may not diffract a point light source.

The thickness of the strands (mother grid alone in particular) may be substantially constant in thickness or may be wider at the base.

The grid (mother grid alone, mother grid and overgrid, overgrid alone) may comprise a main network with strands (optionally that are approximately parallel) and a secondary network of strands (optionally that are approximately perpendicular to the parallel network).

The electroconductive grid (mother grid alone, mother grid and overgrid, overgrid alone) may have a sheet resistance between 0.1 and 30 ohm/square. Advantageously, the electroconductive grid according to the invention may have a sheet resistance less than or equal to 5 ohm/square, or even less than or equal to 1 ohm/square, or even 0.5 ohm/square, especially for a grid thickness greater than or equal to 1 μm, and preferably less than 10 μm or even less than or equal to 5 μm.

The light transmission depends on the B′/A′ ratio of the mean distance between the strands B′ to the mean width of the strands A′.

Preferably, the B′/A′ ratio is between 5 and 15, more preferably still around 10, to easily retain the transparency and facilitate the manufacture, for example, B′ and A′ are respectively equal to around 50 μm and 5 μm.

In particular, a mean strand width A′ is chosen between 100 nm and 30 μm, preferably less than or equal to 10 μm, or even 5 μm in order to limit their visibility, and greater than or equal to 1 μm to facilitate the manufacture and to easily retain a high conductivity and a transparency.

In particular, it is additionally possible to choose a mean distance between strands B′ that is greater than A′, between 5 μm and 300 μm, or even between 20 and 100 μm, to easily retain the transparency.

The thickness of the strands may be between 100 nm and 5 μm, especially micron-sized, more preferably still from 0.5 to 3 μm to easily retain a transparency and a high conductivity.

The grid (mother grid alone, mother grid and overgrid, overgrid alone) according to the invention may be over a large surface area, for example a surface area greater than or equal to 0.02 m², or even greater than or equal to 0.5 m² or to 1 m².

The transfer substrate may be substantially transparent, as already seen. The transfer substrate may have a glass function when it is substantially transparent, and when it is based on inorganic materials (for example, a soda-lime-silica glass) or when it is based on a plastic (such as polycarbonate PC or on polymethyl methacrylate PMMA).

In order to transmit UV radiation, the transfer substrate may preferably be chosen from quartz, silica, magnesium fluoride (MgF₂) or calcium fluoride (CaF₂), a borosilicate glass or a glass with less than 0.05% Fe₂O.

To give examples, for thicknesses of 3 mm:
magnesium or calcium fluorides transmit more than 80%, or even 90%, over the entire range of UV bands, that is to say UVA (between 315 and 380 nm), UVB (between about 280 and 315 nm), UVC (between 200 and 280 nm) and VUV (between about 10 and 200 nm);
quartz and certain high-purity silicas transmit more than 80%, or even 90%, over the entire range of UVA, UVB and UVC bands;
borosilicate glass, such as Borofloat® from Schott, transmits more than 70% over the entire UVA band; and
soda-lime-silica glass with less than 0.05% Fe(III) or Fe₂O₃, especially the glass Diamant® from Saint-Gobain, the glass Optiwhite® from Pilkington, and the glass B270 from Schott, transmit more than 70% or even 80% over the entire UVA band.

However, a soda-lime-silica glass, such as the glass Planilux® sold by Saint-Gobain, has a transmission of more than 80% above 360 nm, which may be sufficient for certain constructions and certain applications.

The transfer substrate may also be chosen for being transparent in a given infrared band, for example between 1 μm and 5 μm. For example, it may be sapphire.

The (overall) light transmission of the transfer substrate coated with the added grid (mother grid alone, mother grid and overgrid, overgrid alone) may be greater than or equal to 50%, more preferably still greater than or equal to 70%, especially is between 70% and 86%.

The (overall) transmission, in a given IR band, for example between 1 μm and 5 μm, of the transfer substrate coated with the added grid (mother grid alone, mother grid and overgrid, overgrid alone) may be greater than or equal to 50%, more preferably still greater than or equal to 70%, especially is between 70% and 86%. The targeted applications are heated glazing units with infrared vision systems, in particular for night vision.

The (overall) transmission, in a given UV band, of the transfer substrate coated with the added grid (mother grid alone, mother grid and overgrid, overgrid alone) may be greater than or equal to 50%, more preferably still greater than or equal to 70%, especially is between 70% and 86%.

Multiple laminated glazing (lamination interlayer of EVA, PU, PVB, silicone, etc. type) may incorporate the transfer substrate with the added grid according to the invention.

The grid according to the invention may be added onto a PC, a hydrophobic substrate, a PET or a PMMA (hydrophobic, not necessarily surface-treated) or a lamination interlayer.

This lamination interlayer makes it possible to simply obtain heated laminated curved glass, for example by avoiding the difficulties of developing bendable grids or those of the compatibility of these microgrids with the enamel (on face 2). This technology makes it possible moreover to easily integrate grids onto small glazing zones.

These grids are assembled by lamination under standard process conditions, without major modification of their electrical or optical characteristics.

The electrical properties of the laminated grids are comparable to those measured on the self-supported grid before lamination. There is no degradation, no significant small power disturbances, etc.

For the busbar (connection system), any technique known for woven grids is used: bonding, soldering, clip fastening, etc.

The grid according to the invention may be used, in particular, as a lower electrode (closest to the substrate) for an organic light-emitting device (OLED), especially a bottom emission OLED or a bottom and top emission OLED.

According to yet another aspect of the invention, it targets the use of a grid such as described previously as:
an active layer (single-layer or multilayer electrode) in an electrochemical and/or electrically controllable device having variable optical and/or energy properties, for example a liquid crystal device or a photovoltaic device, or else an organic or inorganic light-emitting device (TFEL, etc.), a lamp especially a flat lamp or an optionally flat UV lamp;
a heating grid of a heating device, for a vehicle (windshield, rear window, porthole, etc.) or for applications in electrical goods of the radiator, towel warmer or refrigerated cabinet (domestic or professional) type, or a grid for a defrosting, anti-condensation or anti-fogging action;
an electromagnetic shielding grid, for immunizing a device (computer, display screen etc.);
or any other device requiring an (optionally (semi)-transparent) electricoconductive grid.

Thus, the combination of a high-conductivity, transparent electrode on electroactive systems (electrochromics, OLEDs, photovoltaics, flat or tubular discharge lamps, flat or tubular UV lamps) is made possible, the manufacturing steps of which are incompatible with those of the processes for manufacturing microgrids on a substrate.

As a reminder, in electrochromic systems, there are “all solid” electrochromic systems (the term “all solid” being defined, within the context of the invention, in respect of the multilayer stacks for which all the layers are of inorganic nature) or “all polymer” electrochromic systems (the term “all polymer” being defined, within the context of the invention, in respect of the multilayer stacks for which all the layers are of organic nature), or else mixed or hybrid electrochromic systems (in which the layers of the stack are of organic nature and inorganic nature) or else liquid-crystal or viologen systems.

As a reminder, discharge lamps comprise with phosphor(s) as active element. Flat lamps in particular comprise two glass substrates held slightly apart, generally separated by less than a few millimeters, and hermetically sealed so as to contain a gas under reduced pressure, in which an electrical discharge produces radiation generally in the ultraviolet range, which excites a phosphor, which then emits visible light.

Flat UV lamps may have the same structure, naturally for at least one of the walls a material is chosen that transmits UV (as already described). The UV radiation is directly produced by the plasma gas and/or by a suitable additional phosphor.

As examples of flat UV lamps, reference may be made to patents WO 2006/090086, WO 2007/042689, WO 2007/023237 and WO 2008/023124 which are incorporated by reference.

The discharge between the electrodes (anode and cathode) may be non-coplanar (“plane-plane”), with anode and cathode respectively associated with the substrates, via a face or in the thickness, (both internal or external, one internal and the other external, at least one in the substrate, etc.), for example as described in patents WO 2004/015739, WO 2006/090086 or WO 2008/023124 which are incorporated by reference.

In UV lamps and flat lamps, the discharge between the electrodes (anode and cathode) may be coplanar (anode and cathode in one and the same plane, on one and the same substrate) as described in patent WO 2007/023237 which is incorporated by reference.

It may be another type of lighting system, namely an inorganic light-emitting device, the active element being an inorganic light-emitting layer based on a doped phosphor, for example chosen from: ZnS:Cu, Cl; ZnS:Cu,Al; ZnS:Cu, Cl,Mn or else CaS or SrS. This layer is preferably separated from the electrodes by insulating layers. Examples of such glazing are described in document EP 1 553 153 A (with the materials, for example, in table 6).

Liquid crystal glazing may be used as variable light scattering glazing. It is based on the use of a film based on a polymer material and placed between two conductive layers, droplets of liquid crystals, especially nematic liquid crystals having positive dielectric anisotropy, being dispersed in said material. When a voltage is applied to the film, the liquid crystals orient in a preferred direction, thereby allowing vision. With no voltage applied, the crystals not being aligned, the film becomes diffusing and prevents vision. Examples of such films are described, in particular, in European patent EP 0 238 164 and U.S. Pat. No. 4,435,047, U.S. Pat. No. 4,806,922 and U.S. Pat. No. 4,732,456. This type of film, once laminated and incorporated between two glass substrates, is sold by SAINT-GOBAIN GLASS under the brand name Privalite.

In fact, it is possible to use any element based on liquid crystals known under the terms “NCAP” (nematic curvilinearly aligned phases) or “PDLL” (polymer dispersed liquid crystal) or “CLC” (cholesteric liquid crystal).

The latter may also contain dichroic dyes, in particular in solution in the droplets of liquid crystals. It is then possible to jointly modulate the light scattering and the light absorption of the systems.

It is also possible to use, for example, gels based on cholesteric liquid crystals containing a small amount of crosslinked polymer, such as those described in patent WO 92/19695.

The invention also relates to the incorporation of a grid such as obtained from the production of the mask described previously in glazing, operating in transmission.

The term “glazing” should be understood in the broad sense and encompasses any essentially transparent material, having a glass function, that is made of glass and/or of a polymer material (such as polycarbonate PC or polymethyl methacrylate PMMA). The carrier substrates and/or counter-substrates, that is to say the substrates flanking the active system, may be rigid, flexible or semi-flexible.

The invention also relates to the various applications that may be found for these devices, mainly as glazing or mirrors: they may be used for producing architectural glazing, especially exterior glazing, internal partitions or glazed doors. They may also be used for windows, roofs or internal partitions of modes of transport such as trains, planes, cars, boats and worksite vehicles. They may also be used for display screens such as projection screens, television or computer screens, touch-sensitive screens, illuminating surfaces and heated glazing.

The invention will now be described in greater detail with the aid of non-limiting examples and figures:

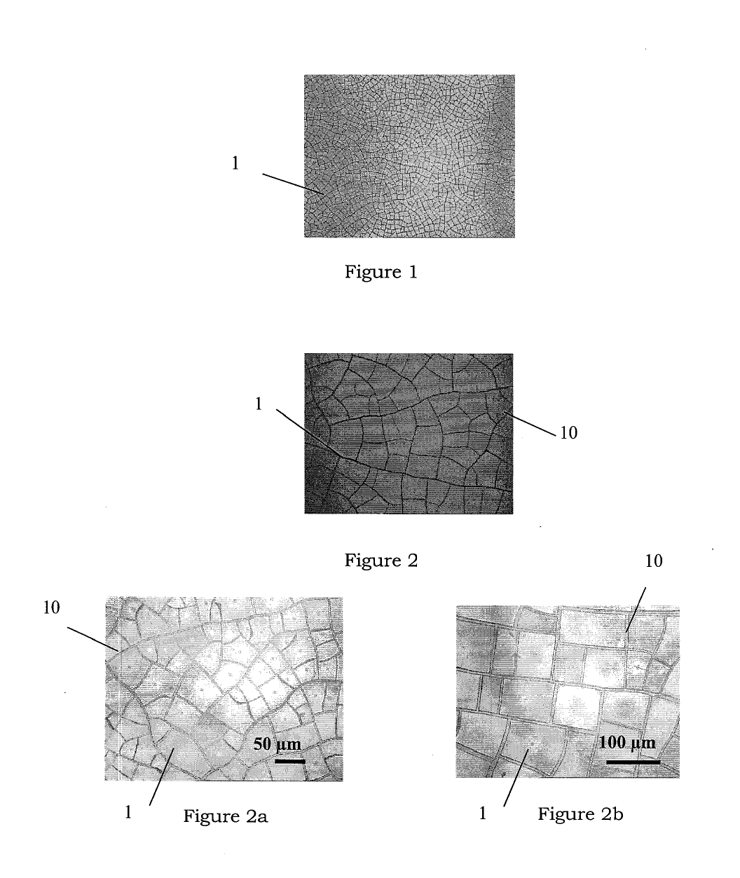

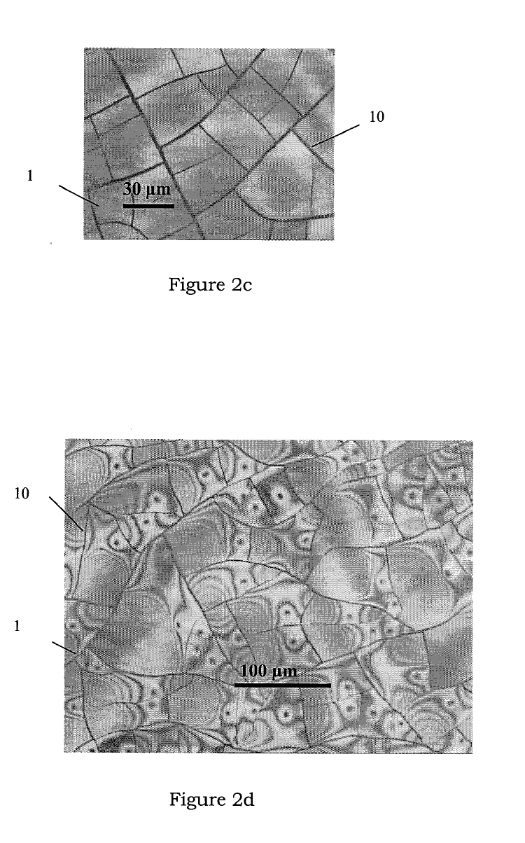

FIGS. 1 to 2d represent examples of network masks used in the process according to the invention;

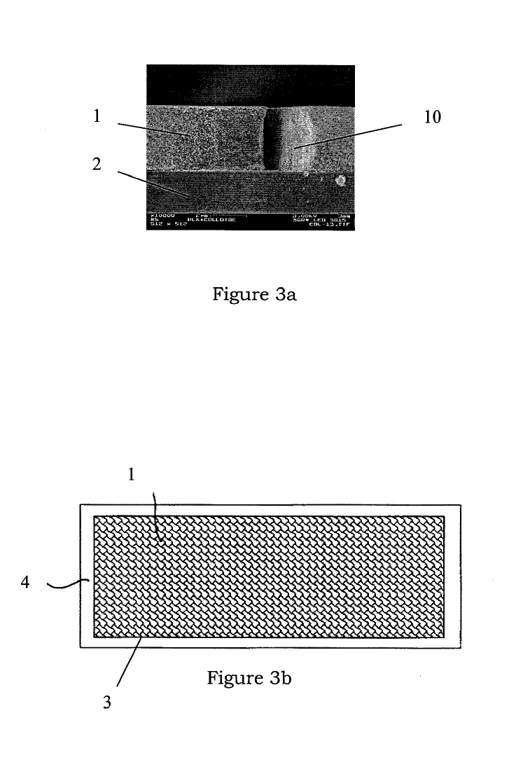

FIG. 3a is an SEM view illustrating the profile of the network mask;

FIG. 3b schematically represents a top view of the network mask according to the invention with one zone free of masking;

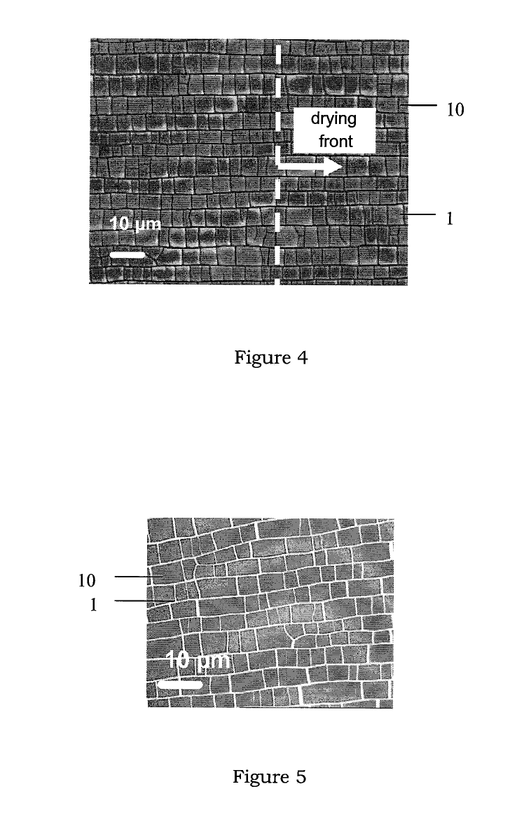

FIGS. 4 and 5 represent masks with different drying fronts;

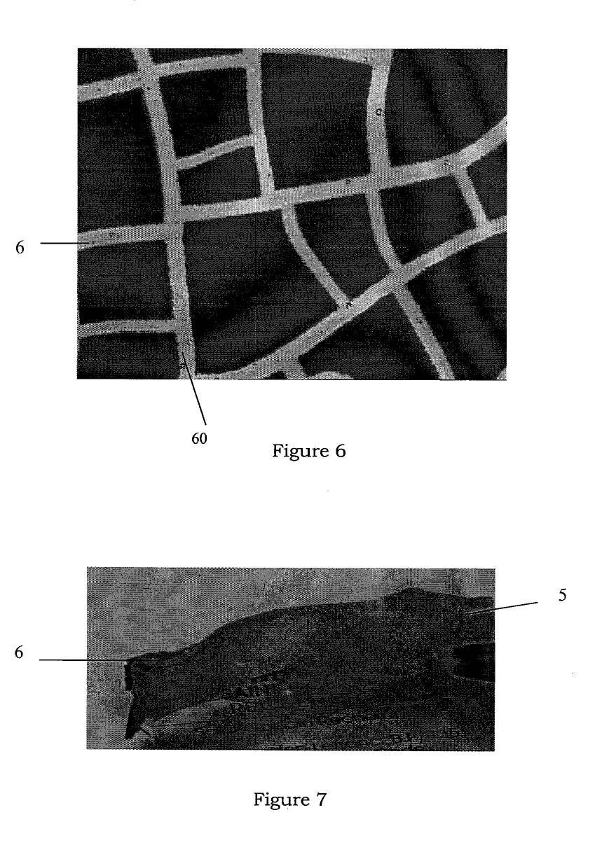

FIG. 6 is an SEM photo of a silver mother grid with a copper overgrid;

FIG. 7 is a photo of a silver mother grid with a self-supported copper overgrid, after detachment;

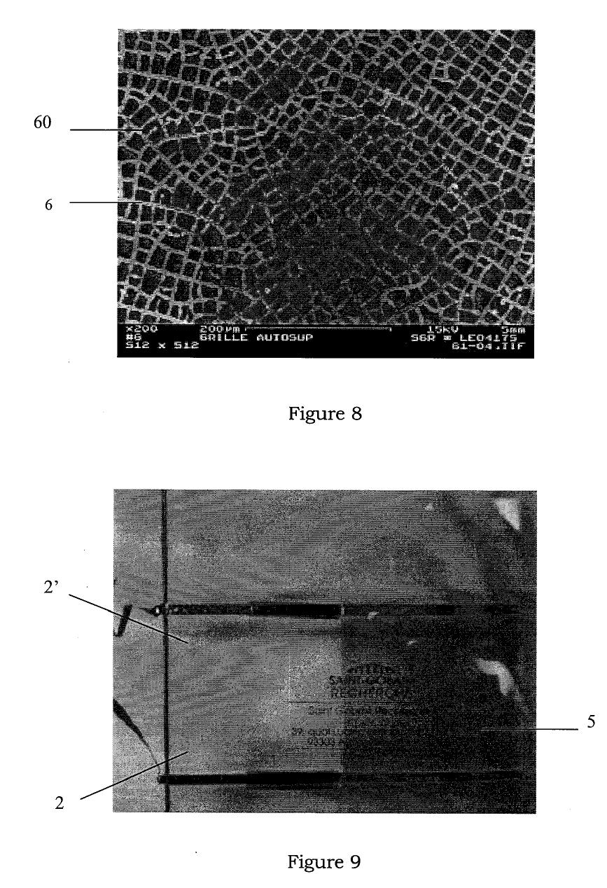

FIG. 8 is an SEM view of a silver mother grid with a self-supported copper overgrid;

FIG. 9 is a photo of a self-supported mother grid and self-supported overgrid together in laminated glazing; and

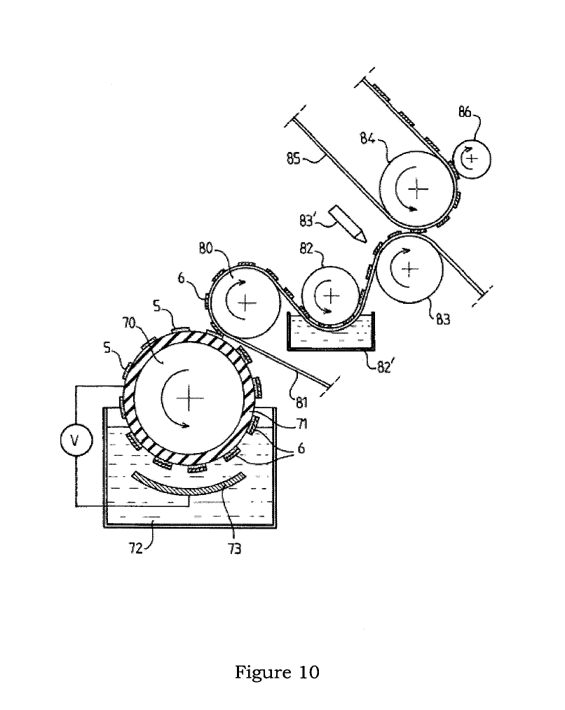

FIG. 10 schematically represents a process for forming an overgrid and for transferring the overgrid alone to a flexible film continuously.

### Manufacture of the Network Mask

A simple emulsion of colloidal particles based on an acrylic copolymer that are stabilized in water at a concentration of 40 wt %, a pH of 5.1 and with a viscosity equal to 15 mPa·s are deposited by a wet route technique, by spin coating, onto a portion of a substrate having a glass function, for example which is flat and inorganic. The colloidal particles have a characteristic dimension between 80 and 100 nm and are sold by DSM under the trademark NEOCRYL XK 52® and have a T_{g} equal to 115° C.

Drying of the layer incorporating the colloidal particles is then carried out so as to evaporate the solvent and form the openings. This drying may be carried out by any suitable process and at a temperature below the T_{g} (hot air drying, etc.), for example at ambient temperature.

During this drying step, the system rearranges itself and forms a network mask 1 comprising a network of openings and mask zones. It depicts patterns, exemplary embodiments of which are represented in FIGS. 1 and 2 (400 μm×500 μm views).

A stable network mask 1 is obtained without resorting to annealing, having a structure characterized by the (mean) width of the opening subsequently referred to as A (in fact the size of the strand) and the (mean) space between the openings subsequently referred to as B. This stabilized network mask will subsequently be defined by the ratio B/A.

A two-dimensional meshed network of openings, with little rupture of the meshes (blocked opening), is obtained.

The influence of the drying temperature was evaluated. Drying at 10° C. under 20% RH results in an 80 μm mesh (FIG. 2a), whereas drying at 30° C. under 20% RH results in a 130 μm mesh (FIG. 2b).

The influence of the drying conditions, especially the degree of humidity, was evaluated. The layer based on XK52 is this time deposited by flow coating which gives a variation in thickness between the bottom and the top of the sample (from 10 μm to 20 μm) resulting in a variation of the mesh size. The higher the humidity is, the smaller B is.

| Drying | Position | Mesh size B (μm) |
|---|---|---|
| 10° C. - 20% humidity | top | 65 |
| 10° C. - 20% humidity | bottom | 80 |
| 10° C. - 80% humidity | top | 45 |
| 10° C. - 80% humidity | bottom | 30 |
| 30° C. - 20% humidity | top | 60 |
| 30° C. - 20% humidity | bottom | 130 |
| 30° C. - 80% humidity | top | 20 |
| 30° C. - 80% humidity | bottom | 45 |

This B/A ratio is also modified by adjusting, for example, the friction coefficient between the compacted colloids and the surface of the substrate, or else the size of the nanoparticles, or even also the evaporation rate, or the initial particle concentration, or the nature of the solvent, or the thickness that is dependent on the deposition technique.

In order to illustrate these various possibilities, an experimental design is given below with 2 concentrations of the colloid solution (C₀ and 0.5×C₀) and various thicknesses deposited by adjusting the ascent rate of the dip coater. It is observed that it is possible to change the B/A ratio by changing the concentration and/or the drying rate. The results are given in the following table:

| | Ascent rate | B: space | A: width | |
|---|---|---|---|---|
| | of the dip | between the | of the | |
| Weight | coater | openings | openings | B/A |
| concentration | (cm/min) | (μm) | (μm) | ratio |
| 20% | 5 | 25 | 3 | 8.4 |
| 20% | 10 | 7 | 1 | 7 |
| 20% | 30 | 8 | 1 | 8 |
| 20% | 60 | 13 | 1.5 | 8.6 |
| 40% | 5 | 50 | 4 | 12.5 |
| 40% | 10 | 40 | 3.5 | 11.4 |
| 40% | 30 | 22 | 2 | 11 |
| 40% | 60 | 25 | 2.2 | 11.4 |

The colloid solution was deposited at the concentration of C₀=40% by using film-drawers of various thicknesses. These experiments show that the size of the strands and the distance between the strands can be varied by adjusting the initial thickness of the colloid layer.

| Thickness | | B: space | A: width | |
|---|---|---|---|---|
| deposited by the | | between the | of the | |
| film-drawer | Weight | openings | openings | B/A |
| (μm) | % | (μm) | (μm) | ratio |
| 30 | 40 | 20 | 2 | 10 |
| 60 | 40 | 55 | 5 | 11 |
| 90 | 40 | 80 | 7 | 11.4 |
| 120 | 40 | 110 | 10 | 11.1 |
| 180 | 40 | 200 | 18 | 11.1 |
| 250 | 40 | 350 | 30 | 11.6 |

Finally, the surface roughness of the substrate was modified by etching, with atmospheric plasma, the surface of the glass via a mask of Ag nodules. This roughness was of the order of magnitude of the size of the contact zones with the colloids which increases the friction coefficient of these colloids with the substrate. The following table shows the effect of changing the friction coefficient on the B/A ratio and the morphology of the mask. It appears that smaller mesh sizes at an identical initial thickness and a B/A ratio which increases are obtained.

| | | B: space | | |
|---|---|---|---|---|
| | Ascent rate | between | A: width | |
| | of the | the | of the | |
| Nanotexturing | dip coater | openings | openings | B/A |
| treatment | (cm/min) | (μm) | (μm) | ratio |
| Yes | 5 | 38 | 2 | 19 |
| Yes | 10 | 30 | 1.75 | 17.2 |
| Yes | 30 | 17 | 1 | 17 |
| Yes | 60 | 19 | 1 | 17.4 |
| Reference | 5 | 50 | 4 | 12.5 |
| Reference | 10 | 40 | 3.5 | 11.4 |
| Reference | 30 | 22 | 2 | 11 |
| Reference | 60 | 25 | 2.2 | 11.4 |

In another exemplary embodiment, the dimensional parameters of the network of openings obtained by spin coating of one and the same emulsion containing the colloidal particles described previously are given below. The various rotational speeds of the spin-coating device modify the structure of the mask.

| | B: space | A: width of | |
|---|---|---|---|
| Rotational | between | the | |
| speed | the openings | openings | B/A |
| (rpm) | (μm) | (μm) | ratio |
| 200 | 40 | 2 | 20 |
| 400 | 30 | 2 | 15 |
| 700 | 20 | 1 | 20 |
| 1000 | 10 | 0.5 | 20 |

The effect of the propagation (cf. FIGS. 5 and 6) of a drying front on the morphology of the mask was studied. The presence of a drying front makes it possible to create a network of approximately parallel openings, the direction of which is perpendicular to this drying front. There is, on the other hand, a secondary network of openings approximately perpendicular to the parallel network, for which the location and the distance between the strands are random.

At this stage of the implementation of the process, a network mask 1 is obtained.

A morphological study of the mask showed that the openings have a straight profile. Reference can be made to FIG. 3a which is a partial transverse view of the mask 1 on the substrate 2 obtained using SEM.

The profile of the openings 10 represented in FIG. 3a has a particular advantage for:
depositing a large thickness of material(s); and
retaining a pattern, in particular of large thickness, that conforms to the mask after having removed the latter.

The mask thus obtained may be used as is or modified by various post-treatments.

The inventors have furthermore discovered that the use of a plasma source as a source for cleaning the organic particles located at the bottom of the opening made it possible, subsequently, to improve the adhesion of the material being used as the grid.

According to this configuration, there are no colloidal particles at the bottom of the openings, there will therefore be a maximum adhesion of the material that is introduced (for example a non-detachable mother grid) in order to fill the opening (this will be described in detail later on in the text) with the substrate having a glass function.

As an exemplary embodiment, cleaning with the aid of an atmospheric-pressure plasma source, with a transferred-arc plasma based on an oxygen/helium mixture, makes it possible both to improve the adhesion of the material deposited at the bottom of the openings and to widen the openings. A plasma source of the brand “ATOMFLOW” sold by Surfx may be used.

In another embodiment, a simple emulsion of colloidal particles based on an acrylic copolymer, which are stabilized in water at a concentration of 50 wt %, a pH of and a viscosity equal to 200 mPa·s is deposited. The colloidal particles have a characteristic dimension of around 118 nm and are sold by DSM under the trademark NEOCRYL XK 38® and have a T_{g} equal to 71° C. The network obtained is shown in FIG. 2c. The space between the openings is between 50 and 100 μm and the range of widths of the openings is between 3 and 10 μm.

In another embodiment, a 40% solution of silica colloids with a characteristic dimension of around 10 to 20 nm, for example the product LUDOX® AS 40 sold by Sigma Aldrich, is deposited. The B/A ratio is around 30, as shown in FIG. 2d.

Typically, it is possible to deposit, for example, between 15% and 50% of silica colloids in an organic (especially aqueous) solvent.

### Partial Removal

The network mask may occupy the entire face of the substrate. Once the network mask is obtained, one or more peripheral zones of the network mask may be removed, for example by blowing, leaving the mask in a zone 3, in order to create a zone free of masking 4, as shown in FIG. 3b.

This removal may consist of:
the removal of one or more peripheral strips of the mask, for example two lateral, parallel (or longitudinal) rectangular strips;
an outlining, the zone free of masking 3 therefore framing the mask 1, as shown in FIG. 3b.

A zone of mechanical reinforcement is thus created.

### Mother Grid Manufacture

After the partial removal of the mask, a grid referred to as a mother grid and a zone of mechanical reinforcement (optionally including a connection zone, of busbar type for example) are produced by electroconductive deposition.

In order to do this, an electroconductive material is deposited electrically through the mask. The material is deposited inside the network of openings so as to fill the openings; the filling being carried out to a thickness at most of around half the height of the mask.

For example, a layer of Ag having a thickness of 300 nm is deposited by magnetron sputtering.

Alternatively, aluminum, copper, nickel, chromium, alloys of these metals, conductive oxides especially chosen from ITC), IZO, ZnO:Al; ZnO:Ga; ZnO:B; SnO₂:F; and SnO₂:Sb may be chosen.

This deposition phase may be carried out, for example, by magnetron sputtering.

Due to this particular grid structure, it is possible to obtain, at a lower cost, an electrode that is compatible with electrically controllable systems while having high electrical conductivity properties.

In order to reveal the grid structure from the mask a “lift off” operation is carried out. This operation is facilitated by the fact that the cohesion of the colloids results from weak van der Waals type forces (no binder, or bonding resulting from annealing). The colloidal mask is then immersed in a solution containing water and acetone (the cleaning solution is chosen as a function of the nature of the colloidal particles), then rinsed so as to remove all the parts coated with colloids. The phenomenon can be accelerated due to the use of ultrasound to degrade the mask of colloidal particles and reveal the complementary parts (the network of openings filled by the material), which will form the grid.

The strands have relatively smooth and parallel edges.

The electrode incorporating the grid according to the invention has an electrical resistivity between 0.1 and 30 ohm/square and a T_{L} of 70 to 86%, which makes its use as a transparent electrode completely satisfactory.

Preferably, especially to achieve this level of resistivity, the mother grid (or overgrid or mother grid and overgrid) has a total thickness between 100 nm and 5 μm.

In these thickness ranges, the electrode remains transparent, that is to say that it has a low light absorption in the visible range, even in the presence of the grid (its network is almost invisible owing to its dimensions).

The grid has an aperiodic or random structure in at least one direction that makes it possible to avoid diffractive phenomena and results in 15 to 25% light occultation.

For example, a grid having metal strands that have a width of 700 nm and are spaced 10 μm apart gives a substrate a light transmission of 80% compared with a light transmission of 92% when bare.

Another advantage of this embodiment consists in that it is possible to adjust the haze value in reflection of the grids.

For example, for an inter-strand spacing (dimension B′) of less than 15 μm, the haze value is around 4 to 5%.

For a spacing of 100 μm, the haze value is less than 1%, with B′/A′ being constant.

For a strand spacing (B′) of around 5 μm and a strand size A′ of 0.3 μm, a haze of around 20% is obtained. Beyond a haze value of 5%, it is possible to use this phenomenon as a means for removing light at the interfaces or a means of trapping light.

Before or after depositing the mask material, it is possible to deposit, in particular by vacuum deposition, a sublayer that promotes the adhesion of the mother grid material (overgrid alone to be detached).

For example, ITO, NiCr or else Ti is deposited and, as grid material, silver.

### Overgrid Manufacture

In order to increase the thickness of the chosen metallic, for example silver, mother grid and thus reduce the electrical resistance of the grid, a copper overlayer (overgrid) was deposited by electrolysis (soluble anode method) on the revealed silver mother grid.

The glass covered with the silver grid constitutes the cathode of the experimental device; the anode is composed of a sheet of copper. It has the role, by dissolving, of keeping the concentration of Cu²⁺ ions, and thus the deposition rate, constant throughout the deposition process.

The electrolysis solution (bath) is an aqueous solution of copper sulfate (CuSO₄.5H₂O=70 gl⁻¹) to which 50 ml of sulfuric acid (H₂SO₄, 10N) are added. The temperature of the solution during the electrolysis is 23±2° C.

The deposition conditions are the following: voltage ≦1.5 V and current ≦1 A.

The anode and the cathode, spaced from 3 to 5 cm apart and of the same size, are positioned parallel in order to obtain perpendicular field lines.

The layers of copper are homogeneous on the silver grids. The thickness of the deposition increases with the electrolysis time and the current density and also the morphology of the deposition. The results are shown in the table below.

| | Reference | With | With | With |
|---|---|---|---|---|
| Sample | 500 nm Ag | 0.5 μm Cu | 1 μm Cu | 2 μm Cu |
| T_{L} (%) | 75 | 70 | 66-70 | 66-68 |
| Haze (%) | 2.5 | 3.0 | 3.0 | 3.2 |
| Sheet R (Ω) | 3 | 2 | 0.2 | 0.1 |

The SEM observations made on these grids show that the size of the meshes is 30 μm±10 μm and the size of the strands is between 2 and 5 μm.

FIG. 6 is an SEM view of a silver mother grid with a copper overgrid 6 with copper strands 60.

The low adhesion of the Ag to the glass, the good intrinsic mechanical strength of the copper grid, the good adhesion of the copper to the silver and the compressive stress in the Cu+Ag layer make it possible to easily detach the microgrid from the substrate.

The larger the thickness of the copper layer deposited by electrolysis on the silver grid is, typically greater than 2 μm, the more readily the grid detaches from its glass substrate without losing its cohesion owing to the good cohesion of the copper electrodeposited on the silver.

It is then easy to transfer it between two interlayers of PVB or polyurethane type that can be laminated.

The silver mother grid 5 with the copper overgrid 6 has been detached from its glass support. FIG. 7 is a photo which shows the self-supported structure (grid and overgrid).

The SEM observations made on this self-supported grid show that the grid is not degraded by the detachment step: the size of the meshes is maintained and the strands are not broken (cf. FIG. 8). The layer of copper deposited remains well adhered to the silver.

FIG. 8 is an SEM photo of the grid which has a size of 16 L×22 L (L being the mean size of the mesh).

Let K be the number of broken strands in this photo, the amount of broken strands is written by definition:

$$T = \frac{K}{2 mn + m + n} \times 100$$

With K=19 (±5), T=2.5% is obtained.

The self-supported structure (grid 5 and overgrid 6) is then laminated with a polyurethane interlayer 2′ between two glasses 2 as shown in FIG. 9.

It displays a high light transmission (and a low haze), and a residual red color in reflection characteristic of the copper.

The electrical properties of the laminated grids are comparable to those measured on the self-supported structure before lamination. There are no degradations or significant small power disturbances.

The structure comprises current feeds in the form of adhesive copper foil.

By way of illustration, this FIG. 9 shows a portion of the glazing 2, on the left without grid and a portion of the glazing 2, on the right, with the self-supported structure (grid 5 and overgrid 6).

In one variant, before depositing the mask material, it is possible to deposit, in particular by vacuum deposition, a sublayer that promotes the adhesion of the mother grid material.

For example, ITO, NiCr or else Ti is deposited and, as grid material, silver.

Onto this mother matrix, a thin layer (<10 nm) of graphite is deposited which acts as a “mold release” agent, and then the copper grid is grown by electroplating as already described. Another mold-release agent may be an organosilane layer.

FIG. 10 schematically represents (not to scale) a process for forming an overgrid by means of a rotating roll 70 and transfer of the overgrid alone continuously to a flexible film.

The mother grid 5 is deposited to the correct dimension on a flexible film of PET 71. The PET is previously rendered hydrophilic by plasma treatment for the deposition of the mask in an aqueous solvent. The metallic silver (or as a variant copper) layer is preferably slightly oxidized at the surface (by plasma). This facilitates the grafting by a fluorinated silane (or as a variant the deposition of a silicone) and renders its surface “non-stick”: this mold release treatment (not shown) is permanent. The metallic layer remains conductive and is used as an electrode.

The film 71 is then attached to the electrolysis roll 70 which is preferably dielectric, for example made of polymer. The electrolysis is carried out: deposition of copper in the electrolysis bath 72 equipped with a counterelectrode 73 which is a constant distance from the mother grid 5.

The thickness of the copper increases gradually as the roll 70 rotates.

The overgrid 6 is passed onto a first transfer roll 80, preferably made of conformable polymer, which supports a perforated or porous film 81 (moving, or even wound flexible film) for example a polymer film of polyolefin type. The tack of the film 81 is adjusted so that the overgrid is transferred by contact from the electrolysis roll 70 to the film 81; however, the overgrid 6 is not bonded to this film.

The 6 is then washed (removal of traces of acid, residual salts, etc.) using a second perforated or porous, for example foam, roll 82. The water passes through the foam and for example is recovered in the washing tank 82′. The perforated film 81 and the overgrid 6 are then dried using compressed air nozzles 83′.

The overgrid 6 is then detached from its perforated film which moves onto a roll 83 or which is wound onto this receiver roll 83 (receiver reel).

Between this roll 83 and a roll 84, a flexible support such as a lamination interlayer 85 (EVA, silicone, PVB, etc.) is introduced, which receives the overgrid 6.

The overgrid 6 is pressed onto the interlayer 85 by means of a last roll 86 which may be heated for example between 30 and 60° C., by exerting a pressure (for example between 3 and 20 Pa) in order to strengthen the adhesion of the overgrid 6.

As a variant, the mother grid is deposited by evaporation for example onto a silica roll.

As mentioned above, the invention may be applied to various types of electrochemical or electrically controllable systems within which the grid may be integrated as an active layer (as an electrode for example). It relates more particularly to electrochromic systems, to liquid crystal or viologen systems, to light-emitting systems (OLEDs, TFELs, etc.), to lamps especially flat lamps, and to UV lamps. The metallic grid thus produced may also equally form a heating element in a windshield, or electromagnetic shielding.

1. A process for manufacturing a submillimetric grid on a main face of a substrate comprising:
producing a mask having submillimetric openings, referred to as a network mask, on the main face, including:
depositing a masking layer from a solution of colloidal nanoparticles that are stabilized and dispersed in a solvent, the nanoparticles having a given glass transition temperature T_{g};
drying the masking layer at a temperature below said temperature T_{g} until the mask having a network of openings with substantially straight edges of mask zones is obtained;
forming the electroconductive grid from the network mask, comprising in this order:
depositing at least one electroconductive material, referred to as grid material, having an electrical resistivity of less than 10⁻⁵ ohm.cm, until a fraction of the depth of the openings is filled;
removing the masking layer, until an electroconductive grid, referred to as the mother grid, is revealed;
optionally depositing, by electrodeposition, an electroconductive material, referred to as overgrid material, directly on the optionally surface-treated grid material, thus forming an overgrid, the surface subjacent to the mother grid then being dielectric;
detaching at least said mother grid or of at least the overgrid, over a thickness of at least 500 nm.

2. The process for manufacturing a grid as claimed in claim 1, wherein, for the detachment of at least the mother grid, a metallic material is deposited by physical vapor deposition as the grid material, in particular silver and/or gold and/or copper, for a thickness of at least 500 nm, deposition on the chosen substrate made of glass, plastic, in particular polyurethane, or deposition on a permanent sublayer referred to as a mold release layer preferably chosen from a layer of fluoropolymer, a layer of carbon, a layer of boron nitride or a layer of stearic acid.

3. The process for manufacturing a grid as claimed in claim 1, wherein a metallic layer is deposited by electrolysis as the overgrid material, in particular copper.

4. The process for manufacturing a grid as claimed in claim 1, wherein, in the case of detachment of at least the mother grid, the process comprises forming a zone of mechanical reinforcement of the grid, by deposition of said electroconductive grid material on an adjacent surface in contact with the network mask, in particular obtained by partial removal of the mask before the electroconductive deposition of the mother grid.

5. The process for manufacturing a grid as claimed in claim 1, wherein for a detachment of the overgrid alone, the mother grid, which is made of a metallic material chosen from gold, silver and/or copper, is deposited on a sublayer for promoting adhesion of the grid material, in particular a layer based on NiCr, Ti, ITO, Al, Nb or on a plastic such as polyethylene terephthalate, polymethyl methacrylate or polycarbonate.

6. The process for manufacturing a grid as claimed in claim 1, wherein for a detachment of the overgrid alone, the mother grid is made of a metallic material chosen from Ti, Mo, W, Co, Nb or Ta, deposited on a glass or on a plastic such as polyethylene terephthalate, polymethyl methacrylate or polycarbonate.

7. The process for manufacturing a grid as claimed in claim 1, wherein for a detachment of the overgrid alone, the metallic mother grid is surface treated with a layer referred to as a mold release layer, in particular an organosilane layer, a layer of carbon, a layer of fluoropolymer, a layer of stearic acid or a layer of boron nitride.

8. The process for manufacturing a grid as claimed in claim 1, wherein the formation of the overgrid and detachment of the overgrid are carried out continuously.

9. The process for manufacturing a grid as claimed in claim 8, wherein:
the mother grid is on a part that rotates about a fixed axis;
the mother grid is partially immersed in an electrolysis bath for the electrodeposition;
on exiting the bath, the overgrid on the mother grid comes into contact with a flexible film on a rotating counterpart for transfer of said overgrid alone.

10. The process for manufacturing a grid as claimed in claim 9, wherein the flexible film is a temporary transfer substrate, which is perforated or porous for washing of the overgrid and the overgrid is transferred by contact without being bonded to said temporary film, and in that after the continuous washing and drying, the overgrid is transferred to another flexible film which is preferably a lamination interlayer.

11. The process for manufacturing a grid as claimed in claim 1, wherein the detachment of at least said mother grid or of at least the overgrid referred to as the detachable part, is carried out:
by applying an adhesive polymer film, having a tack lower than the surface subjacent to the detachable part and having a tack greater than that of the detachable part;
and by removing the polymer film bearing the detached part.

12. The process as claimed in claim 1, wherein the drying of the masking layer is carried out at a temperature of less than or equal to 50° C., preferably at ambient temperature.

13. The process for manufacturing a grid as claimed in claim 1, wherein the solvent is aqueous, the solution of colloids comprises polymeric nanoparticles preferably of acrylic copolymers, styrenes, polystyrenes, polyacrylates, polyesters or mixtures thereof and/or the solution comprises inorganic nanoparticles, preferably of silica, alumina or iron oxide.

14. The process for manufacturing a grid as claimed in claim 1, wherein the solution is aqueous.

15. The process for manufacturing a grid as claimed in claim 1, wherein the masking layer is removed via a liquid route, in particular by a solvent.

16. A detached submillimetric electroconductive grid, obtained by the manufacturing process as claimed in claim 1.

17. The detached submillimetric electroconductive grid as claimed in claim 16, comprising the mother grid and the overgrid.

18. The detached submillimetric electroconductive grid as claimed in claim 16, wherein the grid corresponds to the mother grid or the overgrid.

19. The detached submillimetric electroconductive grid as claimed in claim 16, wherein the mother grid alone or the overgrid alone, or else the mother grid and the overgrid has a ratio of the distance between strands to the submillimetric width of the strands that is between 7 and 40, and/or a strand width between 200 nm and 50 μm and an inter-strand distance between 5 and 500 μm.

20. The detached submillimetric electroconductive grid as claimed in claim 16, wherein the mother grid alone, the overgrid alone or the mother grid and the overgrid has a sheet resistance between 0.1 and 30 ohm/square.

21. The detached submillimetric electroconductive grid as claimed in claim 16, wherein the grid is added to the main face of a substrate, referred to as a transfer substrate, optionally firmly attached to said face.

22. The detached submillimetric electroconductive grid as claimed in claim 21, wherein the transfer substrate is a polycarbonate, a polyethylene terephthalate, a polymethyl methacrylate or a lamination interlayer.

23. The detached submillimetric electroconductive grid as claimed in claim 16, wherein the grid is combined with a main face of a laminated multiple glazing unit in particular in contact with a lamination interlayer.

24. The detached submillimetric electroconductive grid as claimed in claim 16, wherein the light transmission and/or the transmission in the ultraviolet and/or in the infrared of the transfer substrate and of the added grid is between 70% and 86%.

25. A method comprising providing a detached submillimetric electroconductive grid as claimed in claim 16 as an active layer, in particular a heating layer or electrode, in an electrochemical and/or electrically controllable device having variable optical and/or energy properties, in particular a liquid crystal device, or a photovoltaic device, or else a light-emitting device, in particular an organic or inorganic light-emitting device, or else a heating device, or optionally a flat lamp, a flat or tubular UV lamp, an electromagnetic shielding device, or any other device requiring a conductive, in particular transparent, layer.
